(19) United States
(12) Patent Application Publication
(10) Pub. No.: US 2023/0260950 A1
(43) Pub. Date: Aug. 17, 2023

(54) Underfill Dams

(71) Applicant: Google LLC, Mountain View, CA (US)

(72) Inventors: ChanWei Chiu, Taoyuan City (TW); Naiyong Chen, Hayward, CA (US); Yencheng Chen, Tianzhong Township (TW); Guangjun Huang, Shenzhen (CN); Michael J. Lombardi, South Barrington, IL (US); Nael Hannan, Brentwood, CA (US)

(73) Assignee: Google LLC, Mountain View, CA (US)

(21) Appl. No.: 18/306,840

(22) Filed: Apr. 25, 2023

Related U.S. Application Data
(60) Provisional application No. 63/497,931, filed on Apr. 24, 2023.

(51) Int. Cl. H01L 23/00; H01L 25/16

(52) U.S. Cl. CPC H01L 24/32; H01L 25/16; H01L 24/73; H01L 24/16; H01L 2224/73204; H01L 2224/16225; H01L 2224/32225; H01L 2224/26175; H01L 2924/19041; H01L 2224/75611; H01L 24/75

(57) ABSTRACT

This document describes apparatuses and techniques for disposing an underfill dam on a device adjacent to a mounting location for an integrated circuit to direct a flow of underfill toward the mounting location so that the underfill does not flow in undesired directions that may undesirably affect adjacent components.

### CROSS-REFERENCE TO RELATED APPLICATIONS

This application claims priority to U.S. Provisional Application Ser. No. 63/497,931, filed Apr. 24, 2023, the disclosure of which is incorporated herein by reference in its entirety.

### SUMMARY

This document describes apparatuses and techniques for disposing an underfill dam on a device adjacent to a mounting location for an integrated circuit. In aspects the underfill dam is configured to direct a flow of underfill toward the mounting location so that the underfill does not flow in undesired directions that may undesirably affect adjacent components.

In various implementations, an apparatus includes a device configured to receive a surface-mountable integrated circuit at a mounting location on a surface of the device and a plurality of additional components mountable adjacent the mounting location. An underfill dam is disposed on the surface of the device adjacent to a dispensing side of the mounting location. The underfill dam includes a walled structure extending from a proximal section to distal ends to be disposed adjacent to the dispensing side of the mounting location and defining a channel having a dispensing outlet adjacent to the dispensing side of the mounting location. The underfill dam is configured to receive a supply of underfill from a dispensing nozzle into the channel and to direct the underfill to flow out of the dispensing outlet toward the dispensing side of the mounting location.

This Summary is provided to introduce apparatuses and techniques for disposing the underfill dam on the device adjacent to the mounting location to direct the flow of underfill toward the mounting location. This Summary is not intended to identify essential features of the claimed subject matter, nor is it intended for use in determining the scope of the claimed subject matter.

### BRIEF DESCRIPTION OF THE DRAWINGS

The details of one or more aspects of apparatuses and techniques for disposing an underfill dam on a device adjacent to a mounting location to direct a flow of underfill toward the mounting location are described in this document with reference to the following drawings. The same numbers are used throughout the drawings to reference like features and components.

FIG. 1A is a schematic view of a device on which an underfill dam is disposed adjacent to a mounting location for an integrated circuit;

FIG. 1B is a schematic view of a walled structure of the underfill dam of FIG. 1A;

FIG. 2A is a partial cross-sectional view of an underfill dam directing underfill through a dispensing outlet formed by the walled structure of FIG. 1B;

FIG. 2B is a schematic view of the device of FIG. 1A on which underfill has been deposited as directed by the underfill dam;

FIGS. 3A, 3D, 3E, and 3F are schematic views of walled structures formable by deposition of a flowable material on a device;

FIGS. 3B and 3C are perspective views of a flowable material deposited on a device to form walled structures of FIGS. 3A, 3D, 3E, and 3F;

FIGS. 4A and 4D are schematic views of walled structures formed for attachment to a device;

FIGS. 4B, 4C, 4E, and 4F are perspective views of the walled structures of FIGS. 4A and 4D being installed on devices to form underfill dams;

FIGS. 5A, 5B, and 5C are schematic views of configurations of devices to support an underfill dam in directing the underfill toward the mounting location; and

FIG. 6 is a flow diagram of an example method of implementing an underfill dam to direct a flow of underfill toward a mounting location on a surface of a device.

### DETAILED DESCRIPTION

### Overview

In securing a surface-mounted integrated circuit to a device such as a printed circuit board (PCB), underfill is sometimes used to further secure a mechanical connection between the integrated circuit and the device. The underfill typically includes a low-viscosity suspension, such as a polymer, curable polymer, filling material, epoxy, or another glue. The underfill may reinforce the mechanical connection provided by a ball grid array (BGA) or land grid array (LGA) of solder balls in securing the integrated circuit to the device. The underfill is typically supplied by a dispensing nozzle which jets a quantity of underfill adjacent to a mounting location where the integrated circuit is soldered to the device. By capillary action, the underfill is drawn beneath the integrated circuit and around the BGA or LGA. The underfill, once cured, encapsulates the BGA or LGA and supports mechanical and electrical connections between the integrated circuit and the device to protect the integrity of the connections when the device including the integrated circuit is dropped and/or during thermal cycling of the device.

Unfortunately, underfill may create problems with components on the device adjacent to the integrated circuit. For example, a portion of the underfill, instead of flowing beneath the integrated circuit, may flow across the surface of the device and solidify against the adjacent components. When one or more of the adjacent components includes a multi-layer ceramic capacitor (MLCC) or another pressure-sensitive component, mechanical force resulting from thermal expansion of the MLCC against the underfill and/or mechanical drop and/or tumble may result in failure of the MLCC and, thus, failure of the device.

This document describes apparatuses and techniques for disposing an underfill dam on a device adjacent to a mounting location to direct a flow of underfill toward the mounting location. By directing the flow of underfill toward the mounting location, the apparatuses and techniques may assist the underfill in flowing to its intended destination and, thus, avoid undesirable effects of an unintended deposit of underfill interfering with adjacent components.

### Example Apparatuses

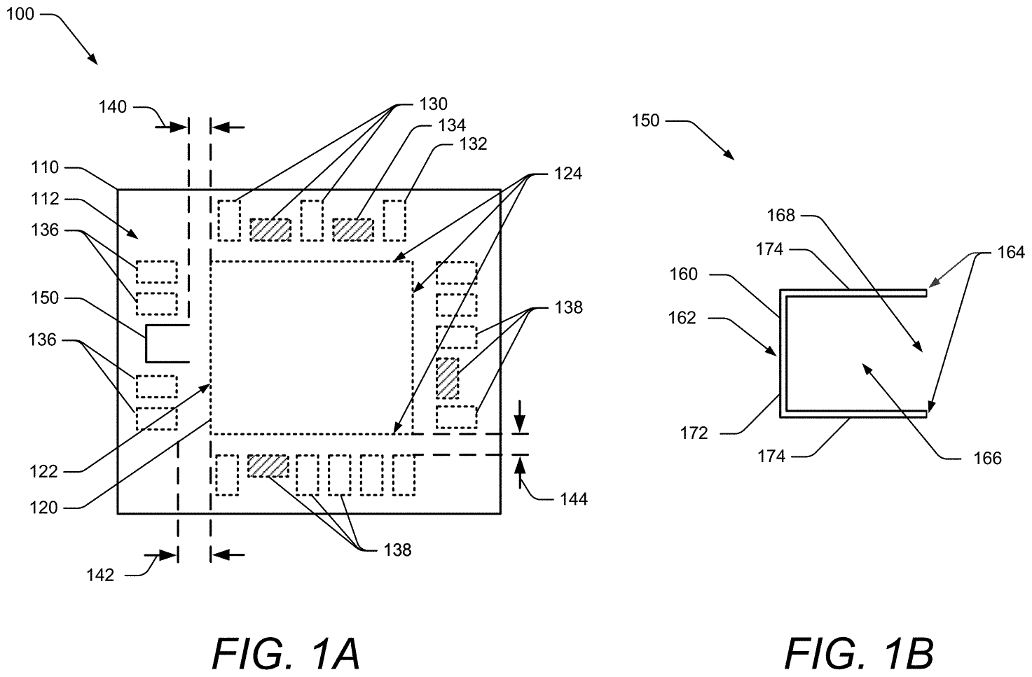

FIG. 1A illustrates a system 100 that includes an underfill dam 150 disposed on a surface 112 of a device 110 configured to receive a surface-mountable integrated circuit (not shown in FIG. 1A). In the examples of FIGS. 1A-5C, the device 110 is shown as a printed circuit board (PCB). However, the device 110 configured to receive the integrated circuit also may include another type of circuit or device, such as a base integrated circuit configured to have one or more additional devices mounted in one or more additional layers thereon.

The surface 112 of the device 110 includes a mounting location 120 (represented with a dotted line in FIG. 1A) configured to receive an integrated circuit (not shown in FIG. 1A). The integrated circuit may include a power-management integrated circuit (PMIC) or another circuit that is surface-mountable to the device 110 using solder balls in a ball grid array (BGA) or land grid array (LGA; neither of which is shown in FIG. 1A). The mounting location 120 may include a dispensing side 122, where the underfill dam 150 is disposed to receive a supply of underfill (not shown in FIG. 1A) and direct the underfill toward the mounting location 120, and a plurality of non-dispensing sides 124.

The device 110 also may be configured to receive one or more additional components 130 (also represented with dotted lines in FIG. 1A). The additional components 130 may include one or more multi-layer ceramic capacitors (MLCCs) 132 and other components 134 (represented as shaded areas to be distinct from the MLCCs 132). For sake of illustration, it is considered that the MLCCs 132 may represent a type of additional component 130 that may be more susceptible to damage caused by being impinged upon by an unintended underfill deposit (not shown). Mechanical force applied to the MLCCs 132 as a result of the underfill impinging upon the MLCCs 132 can cause the MLCCs 132 to crack and, thus, fail. By contrast, other components 134 may not be as susceptible to damage from impingement of the underfill.

The underfill dam 150, as further described below, is disposed (e.g., positioned) at a first distance 140 from the dispensing side 122 of the mounting location 120. In some implementations, as described further below, proximal adjacent components 136 along the dispensing side 122 may be disposed at a second distance 142 from the dispensing side 122, where the second distance 142 may be greater than the first distance 140. The difference between the second distance 142 and the first distance 140 may provide a margin to enable the underfill to be delivered within the mounting location 120 under the integrated circuit (not shown in FIG. 1A) without impinging upon the proximal adjacent components 136 along the dispensing side 122. Non-proximal adjacent components 138 along the non-dispensing sides 124 of the mounting location 120 may be disposed at a third distance 144 from one of the non-dispensing sides 124. The third distance 144 may be less than or greater than either the first distance 140 or the second distance 142. If a quantity of underfill (not shown in FIG. 1A) is not excessive, capillary action may help to contain the underfill within the mounting location 120 between the integrated circuit (not shown in FIG. 1A) and surface 112 of the device 110. Thus the third distance 144 may be shorter than the second distance 142 or the first distance 140 without the underfill materially impinging upon the non-proximal adjacent components 138.

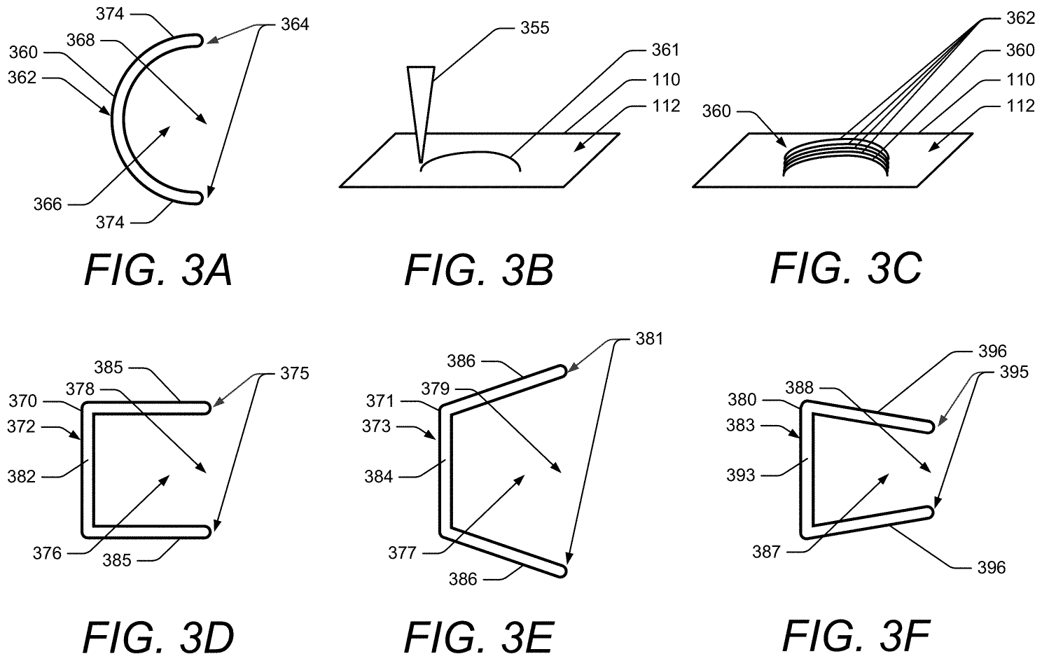

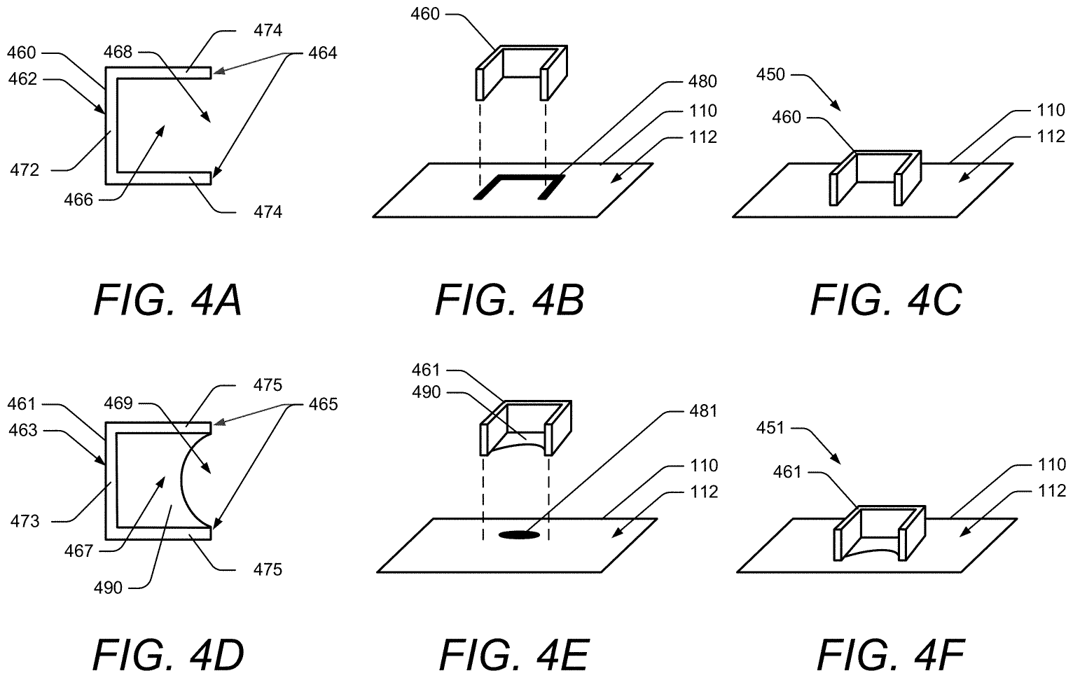

Referring to FIG. 1B, in various implementations, the underfill dam 150 may include a walled structure 160. The walled structure 160 may be formed on or attached to the surface 112 of the device 110 (FIG. 1A), as further described below with reference to FIGS. 3A-4C. The walled structure 160 extends from a proximal section 162 to distal ends 164. The distal ends 164 are to be disposed adjacent to the dispensing side 122 of the mounting location 120 (FIG. 1A). The proximal section 162 may include a proximal wall 172 that is continuously formed with or is joined to side walls 174 that extend from the proximal section 162 to the distal ends 164. The walled structure 160 may include a curved or nonlinear structure or may be a multi-sided structure, as further described below with reference to FIGS. 3A-4C. The walled structure 160 defines a channel 166. When the walled structure 160 is disposed on the surface 112 of the device 110, a supply of underfill (not shown in FIG. 1B) received into the channel 166 is directed by the walled structure 160 toward a dispensing outlet 168 between the distal ends 164 of the walled structure 160.

Also, although not shown expressly shown in the figures, the walled structure 160 may include a single, generally straight wall adjacent to the dispensing side 122 of the mounting location 120. Depositing underfill between a walled structure 160 including a single, generally straight form and the dispensing side 122 of the mounting location 120 would at least partially contain the underfill against the dispensing side 122 of the mounting location 120 while capillary action draws the underfill toward the mounting location, as described further below.

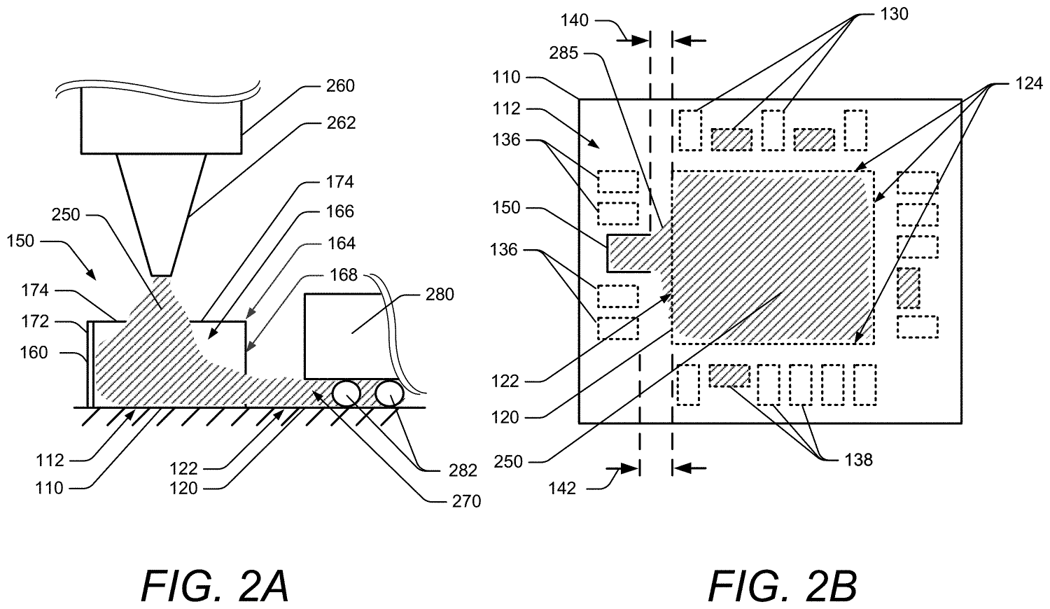

Referring to FIGS. 2A and 2B, implementations of the underfill dam 150 may help to direct a flow of underfill 250 to prevent the underfill 250 from flowing toward and accumulating in unintended locations. The underfill dam 150 of FIGS. 2A and 2B, for the sake of example, is of the form described with reference to FIG. 1B, with the walled structure 160 having the proximal wall 172 and the side walls 174 that define the channel 166 and the dispensing outlet 168 at the distal ends 164 of the walled structure 160.

Referring to FIG. 2A, the underfill 250 is supplied by a dispensing nozzle 260 through a jetting valve 262 or similar outlet into the channel 166 defined by the walled structure 160. When the supply of the underfill 250 impinges upon the walled structure 160 and/or the surface 112 of the device 110, the walled structure 160 directs the underfill 250 to flow through the channel 166 toward the distal ends 164 of the walled structure 160 and out through the dispensing outlet 168 between the distal ends 164 of the walled structure 160. The underfill 250 is thus directed toward a gap 270 between an integrated circuit 280 and the surface 112 of the device 110, around solder balls 282 coupling the integrated circuit 280 to the device 110. Once presented at the gap 270 between the integrated circuit 280 and the surface 112 of the device 110, the underfill 250 may be drawn by capillary action to fill a space between the integrated circuit 280 and the surface 112 of the device 110.

It will be appreciated that the proximal wall 172 blocks the underfill 250 from flowing diametrically away from the gap 270 between the integrated circuit 280 and the surface 112 of the device 110. At the same time, the side walls 174 restrict or limit the underfill 250 from flowing laterally to the gap 270 between the proximal wall 172 and the distal ends 164. Thus, the underfill dam 150 directs the flow of the underfill 250 toward the gap 270 between the integrated circuit 280 and the surface 112 of the device 110 while preventing the underfill 250 from flowing in unintended directions.

Referring particularly to FIG. 2B, as a result of the underfill dam 150 directing the underfill 250 toward the mounting location 120, the underfill 250 may be drawn between the integrated circuit 280 (not shown in FIG. 2B) and the surface 112 of the device 110. By being directed toward the mounting location 120, the underfill 250 is directed away from the proximal adjacent components 136 at the dispensing side 122 of the mounting location 120. There may be some lateral seepage 285 of the underfill 250 between the underfill dam 150 and mounting location 120. However, particularly in implementations in which the underfill dam 150 is disposed at a first distance 140 from the dispensing side 122 of the mounting location 120 that is less than a second distance 142 at which the proximal adjacent components 136 are disposed from the dispensing side 122 of the mounting location 120, the lateral seepage 285 may not impinge upon the proximal adjacent components 136. For example, in various implementations, the second distance 142 may be selected as 0.3 mm and the first distance 140 may be selected as 0.1 mm.

The disparity between the first distance 140 and the second distance 142 may help prevent the underfill 250 from reaching the proximal adjacent components 136. Correspondingly, unless the supply of the underfill 250 is excessive, the underfill 250 may be contained within the mounting location 120 and should not reach the other adjacent components 138 on the non-dispensing sides 124 of the mounting location 120. Further, when the underfill 250 is directed to the mounting location 120 by the underfill dam 150, less underfill 250 should be needed than in cases in which the underfill 250 is deposited adjacent the mounting location 120, relying on capillary action to draw the underfill 250 to the mounting location 120.

Referring to FIGS. 3A-4F, it should be emphasized that the walled structure 160 (FIGS. 1A-2B) may be formed in different shapes and fabricated in different ways. Referring specifically to FIGS. 3A-3F, walled structures 360, 370, 371, and 380 may be formed by depositing one or more layers of a flowable material, such as a gel, a flowable silicone or another polymer, or another thermal or ultraviolet (UV) cured material that solidifies (as a result of its composition and/or by being subjected to curing) onto the surface 112 of the device 110. Moreover, the walled structures 360, 370, 371, and 380 may have various curved or multi-sided shapes. A walled structure also may include a combination of one or more straight, curved, or multi-sided shapes described herein.

Referring particularly to FIG. 3A, the walled structure 360 includes a curved shape. The walled structure 360 includes at least one curved side wall 374 extending from a proximal section 362 to distal ends 364. The walled structure 360 defines a channel 366 leading to a dispensing outlet 368. Analogous to the underfill dam 150 of FIGS. 1A-2B, the curved walled structure 360 may cause a supply of underfill (not shown in FIG. 3A) to flow toward the dispensing outlet 368 toward a dispensing side of a mounting position (neither of which are shown in FIG. 3A) to direct a flow of underfill.

Referring to FIGS. 3B and 3C, the walled structure 360 of FIG. 3A may be formed by depositing a flowable material on the surface 112 of the device 110. In one implementation, one or more passes of a deposition nozzle 355 may be used to build up the walled structure 360 (FIG. 3A). FIG. 3B shows the deposition nozzle 355 after making a pass over the surface 112 of the device 110 in a shape of the walled structure 360 to create a layer 361 of the walled structure 360 (not shown in FIG. 3B). FIG. 3C shows the walled structure 360 as it is built up after completion of a series of passes by the deposition nozzle 355 (FIG. 3B) upon the surface 112 of the device 110.

Using the techniques described with reference to FIGS. 3B and 3C, a walled structure may be formed of a flowable material in any number of shapes. For example, FIGS. 3D-3F show a plurality of the multi-sided walled structures 370, 371, and 380 of different shapes. FIG. 3D shows the multi-sided walled structure 370 that is similar in shape to the walled structure 160 of the underfill dam 150 of FIGS. 1A-2B. The walled structure 370 includes generally straight side walls 385 that extend at generally right angles from a generally straight proximal wall 382 at a proximal section 372 to distal ends 375. The walled structure 370 defines a channel 376 leading to a dispensing outlet 378 between the distal ends 375.

FIG. 3E shows the multi-sided walled structure 371 having one or more flared side walls 386. The walled structure 371 includes the generally straight side walls 386 that extend at oblique angles from a generally straight proximal wall 384 at a proximal section 373 to distal ends 381. The walled structure 371 thus defines a widening channel 377 leading to a wider dispensing outlet 379 between the distal ends 381. The walled structure 371 prevents a supply of underfill from flowing diametrically away from a dispensing side of a mounting location (not shown in FIG. 3E). The wider dispensing outlet 379 may allow more of a lateral flow along the dispensing side than the dispensing outlet 378 (FIG. 3D) that is not defined by flared side walls 386, but the wider dispensing outlet 379 may still direct a flow of underfill generally toward the dispensing side and away from adjacent components (not shown in FIG. 3E) disposed next to the walled structure 371.

FIG. 3F, by contrast, shows the multi-sided walled structure 380 having one or more inwardly-tapering side walls 396. The walled structure 380 includes the generally straight side walls 396 that extend at acute angles from a generally straight proximal wall 393 at a proximal section 383 to distal ends 395. The walled structure 380 defines a narrowing channel 387 leading to a narrowed dispensing outlet 388 between the distal ends 395. By contrast with the walled structure 371 of FIG. 3E, the narrowed dispensing outlet 388 may more stringently restrict a supply of underfill from flowing laterally along the dispensing side (not shown in FIG. 3F). It will be appreciated that differently shaped walled structures may be used in underfill dams to suit design choices. The choice of shape may be based on density and proximity of the proximal adjacent components 136, viscosity of a selected underfill material, and other factors.

Instead of being formed directly on the surface 112 of the device 110 (FIG. 1A), the walled structure 160 (FIG. 1A-2B) may be formed as a separate object and then attached to the surface 112 of the device 110 to form the underfill dam 150 (FIGS. 1A-2B). FIG. 4A shows a multi-sided walled structure 460 that may be stamped or otherwise formed of metal, injection-molded out of plastic, three-dimensionally printed, or otherwise formed. The walled structure 460 is similar in shape to the walled structure 160 of the underfill dam 150 of FIGS. 1A-2B. The walled structure 460 includes generally straight side walls 474 that extend at generally right angles from a generally straight proximal wall 472 at a proximal section 462 to distal ends 464. The walled structure 460 defines a channel 466 leading to a dispensing outlet 468 between the distal ends 464.

Referring to FIGS. 4B and 4C, the walled structure 460 may be attached to the surface 112 of the device 110 with a bonding layer 480 deposited on the surface 112 to engage the walls 472 and 474 of the walled structure 460. The bonding layer 480 may include an adhesive, solder, or another material configured to secure the walled structure 460 to the device 110. It will be appreciated that the bonding layer 480 may be shaped to correspond precisely to the walls 472 and 474 of the walled structure 460. Alternatively, the bonding layer 480 may extend beyond a footprint of the walled structure 460. In either case, when the bonding layer 480 sealably joins the walled structure 460 to the surface 112 to form an underfill dam 450 of FIG. 4C, the underfill dam 450 will prevent underfill from seeping beneath the walled structure 460 and thereby circumventing the underfill dam 450.

FIG. 4D shows a walled structure 461 that is similar in shape to the walled structure 460 of the underfill dam 450 of FIGS. 4A-4C but also includes a bottom surface 490 extending from a proximal wall 473 at a proximal section 463 and along side walls 475. The bottom surface 490 may extend partially or fully toward a dispensing outlet 469 between distal ends 465 beneath a channel 467 defined by the walls 473 and 475. Inclusion of the bottom surface 490 may help to ensure that underfill cannot seep between the walled structure 461 and the surface 112 of the device 110.

Referring to FIGS. 4E and 4F, the walled structure 461 may be attached to the surface 112 of the device 110 with a bonding layer 481 deposited on the surface 112 to engage the walls 472 and 474 of the walled structure 460. The bottom surface 490 may provide a convenient lower surface of the walled structure 461 with which to attach the walled structure 461 to the surface 112 of the device 110. As in the case of the walled structure 460 of FIGS. 4A-4C, it will be appreciated that the bonding layer 481 may be shaped to correspond precisely to a footprint of the walled structure 461 or the bonding layer 481 may extend beyond a footprint of the walled structure 461 in attaching the walled structure 461 to the surface 112 of the device 110 to form a underfill dam 451.

For the sake of example, the walled structures 460 and 461 may have a width across the distal ends 464 and 465 of 1.2 mm, a height of 0.65 mm, and a depth from the proximal sections 462 and 463 of 1.0 mm, respectively. The walls 472, 474, 473, and 475 may have a thickness of 0.1 mm.

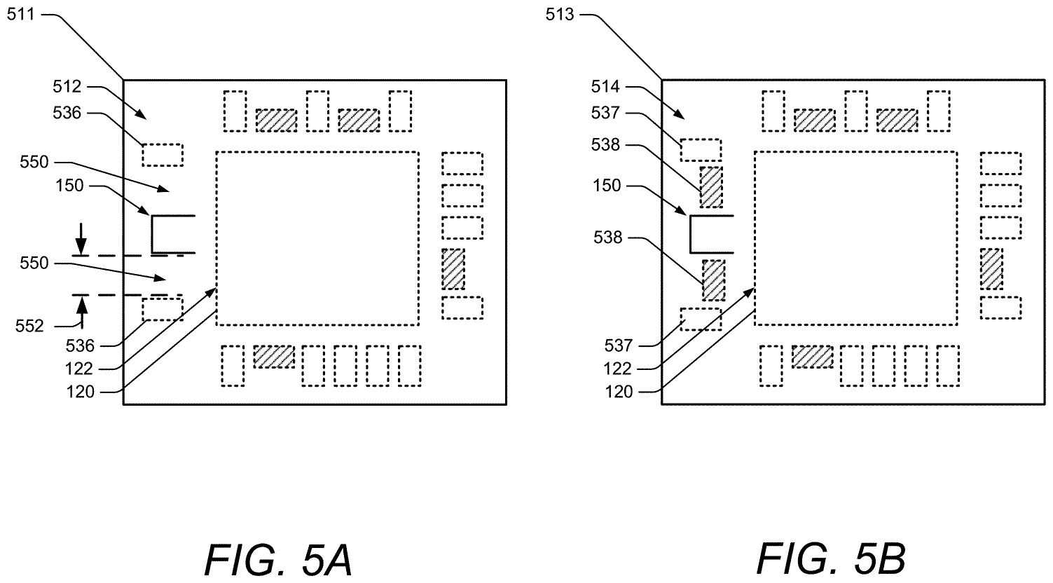

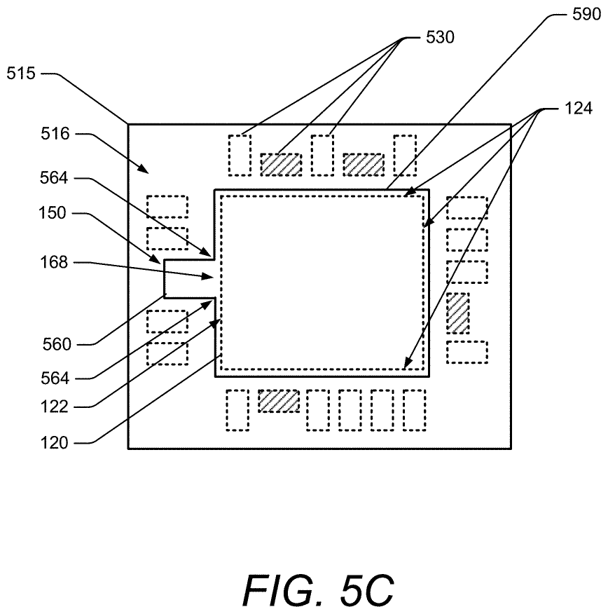

Referring to FIGS. 5A-5C, adjustments may be made to configurations of devices 511, 513, and 515, respectively, to support operation of the underfill dam 150 in directing the flow of underfill. Although FIGS. 5A-5C depict the underfill dam 150 as having the generally straight side walls 174 extending at generally right angles from the proximal wall 172, the configurations described with reference to FIGS. 5A-5C may be used with other configurations of underfill dams as previously described with reference to FIGS. 3A-4F.

Referring to FIG. 5A, on a surface 512 of the device 511 at the dispensing side 122 of the mounting location 120, one or more buffer regions 550 may be included laterally adjacent to the underfill dam 150 on the dispensing side 122 of the mounting location 120. The buffer regions 550 have a width 552 across the surface 512 of the device 511 between the underfill dam 150 and proximal adjacent components 536 to either side of the underfill dam. Providing the buffer regions 550 between the underfill dam 150 and the proximal adjacent components 536 may protect the proximal adjacent components 536 from the lateral seepage 285 of the underfill 250 (FIG. 2B) as previously described.

Alternatively, referring to FIG. 5B, instead of or in addition to including the buffer regions 550 of FIG. 5A, selective arrangement of MLCCs 537 and other proximal adjacent components 538 on the dispensing side 122 of the mounting location 120 on a surface 514 of the device 513 may avoid potential damage to the MLCCs 537 and other proximal adjacent components 538. For the sake of example, as previously described with reference to FIG. 1A, the MLCCs 537 may be more susceptible to damage as a result of being impinged upon by an unintended deposit of underfill than the other proximal adjacent components 538. By configuring the device 513 so that the MLCCs 537 are not immediately adjacent to the underfill dam 150, the lateral seepage 285 of the underfill 250 (FIG. 2B) may be less likely to impinge upon the MLCCs 537.

Referring to FIG. 5C, a perimeter barrier 590 may be disposed on a surface 516 of the device 515 extending from distal ends 564 of a walled structure 560 of the underfill dam 150. In various implementations, the perimeter barrier 590 extends from the distal ends 564 on either side of the dispensing outlet 168 of the walled structure 560. The perimeter barrier 590 extends along the dispensing side 122 and around the non-dispensing sides 124 of the mounting location 120. The perimeter barrier 590 acts as a levy to contain the underfill 250 (FIG. 2B) within its boundaries to prevent the underfill 250 from flowing outside the mounting location 120 and impinging upon additional components 530 arranged around the mounting location 120. The perimeter barrier 590, in various implementations, may be formed by depositing traces of a flowable material, such as silicone or another material, around the mounting location 120. In various implementations, the perimeter barrier 590 may be integrally formed with the walled structure 360 or separately formed to operate in conjunction with various other forms of walled structures.

### Example Method

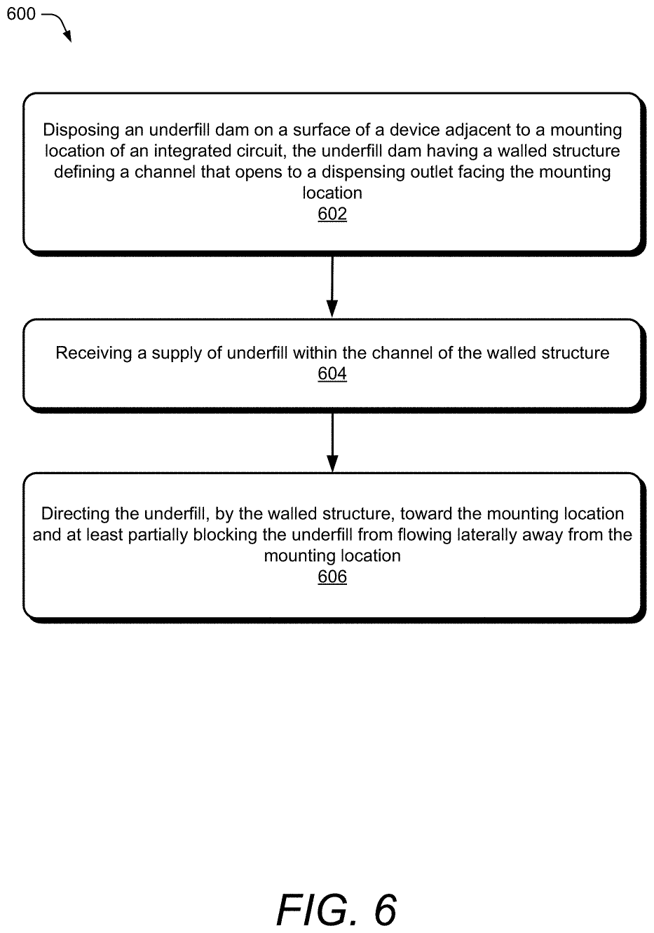

An example method 600 is described with reference to FIG. 6 in accordance with one or more aspects of using an underfill dam as previously described. Generally, the method 600 illustrates sets of operations (or acts) that may be performed in, but are not necessarily limited to, the order or combinations in which the operations are shown herein. Further, any of one or more of the operations may be repeated, combined, reorganized, skipped, or linked to provide a wide array of additional and/or alternate methods. In portions of the following discussion, reference may be made to the apparatuses or configurations of FIGS. 1A-FIG. 5C, reference to which is made for example only. The techniques and apparatuses described in this disclosure are not limited to an implementation or performance by one entity or multiple entities operating on one device or those described with reference to the figures.

FIG. 6 illustrates the example method 600 of implementing an underfill dam and using the underfill dam to direct a flow of underfill toward a mounting location on a surface of a device as previously described with reference to FIGS. 1A-5C. At a block 602, an underfill dam is disposed on a surface of a device adjacent to a mounting location of an integrated circuit, the underfill dam having a walled structure defining a channel that opens to a dispensing outlet facing the mounting location. The underfill dam, for example, may include the underfill dam 150 disposed adjacent the mounting location 120 on the surface 112 of the device 110 described with reference to FIG. 1A. At a block 604, a supply of underfill is received within the channel of the walled structure, as described with reference to FIG. 2A in which the underfill 250 is received from the dispensing nozzle 260. At a block 606, the underfill is directed toward the mounting location by the walled structure and is at least partially blocked from flowing laterally away from the mounting location by the walled structure, as described with reference to FIG. 2B.

The preceding discussion describes apparatuses and techniques for disposing an underfill dam on a device adjacent to a mounting location for an integrated circuit to direct a flow of underfill toward the mounting location so that the underfill does not flow in undesired directions that may undesirably affect adjacent components. These apparatuses and techniques may be realized using one or more of the entities or components shown in FIGS. 1A-5C, which may be further divided, combined, and so on. Thus, these figures illustrate some of the many possible systems or apparatuses capable of employing the described techniques.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although implementations of apparatuses and techniques for underfill dams have been described in language specific to certain features and/or methods, the subject of the appended claims is not necessarily limited to the specific features or methods described. Rather, the specific features and methods are disclosed as example implementations of underfill dams configured for directing a flow of underfill received from a dispensing nozzle toward a mounting location on a device.

What is claimed is:

1. An apparatus comprising:
a device configured to receive a surface-mountable integrated circuit at a mounting location on a surface of the device and at least one additional component mountable adjacent the mounting location; and
an underfill dam disposed on the surface of the device adjacent to a dispensing side of the mounting location, the underfill dam having a walled structure extending from a proximal section to distal ends disposed adjacent the dispensing side of the mounting location and defining a channel having a dispensing outlet adjacent the dispensing side of the mounting location, wherein the underfill dam is configured to receive a supply of underfill receivable from a dispensing nozzle into the channel and to direct the underfill to flow out of the dispensing outlet toward the dispensing side of the mounting location.

2. The apparatus of claim 1, wherein the underfill dam includes at least one layer of a flowable material deposited on the surface of the device.

3. The apparatus of claim 1, wherein the underfill dam includes a structure formed separately from the device and attached to the surface of the device.

4. The apparatus of claim 3, wherein the underfill dam includes a bottom surface extending from the proximal section at least partially toward the distal ends, wherein the bottom surface is configured to be mounted on the surface of the device.

5. The apparatus of claim 1, wherein the walled structure includes a curved structure.

6. The apparatus of claim 1, wherein the walled structure includes a multi-sided structure and the proximal section includes a proximal wall joined to side walls terminating at the distal ends.

7. The apparatus of claim 1, wherein the distal ends of the walled structure are positioned at a first distance from the mounting location, and the first distance is less than a second distance at which an additional component is disposed from the mounting location on the dispensing side.

8. The apparatus of claim 1, wherein the device is configured to include at least one buffer region laterally adjacent to the underfill dam on the dispensing side of the mounting location between the underfill dam and a next adjacent component.

9. The apparatus of claim 1, wherein the device is configured not to receive components other than a multi-layer ceramic capacitor adjacent to the underfill dam.

10. The apparatus of claim 1, further comprising a perimeter barrier extending from the distal ends of the walled structure on either side of the dispensing outlet and around a perimeter of the mounting location.

11. The apparatus of claim 1, wherein the device includes one of a printed circuit board (PCB) and a base integrated circuit configured to receive the surface-mountable integrated circuit.
